(19) United States
(12) Patent Application Publication
(10) Pub. No.: US 2007/0119366 A1
(43) Pub. Date: May 31, 2007

(54) Section forming method & construction for wafer ingot growth

(75) Inventors: C.W. Lan, Hsinchu (TW); Wen-Ching Hsu, Hsinchu (TW); Kimsam Hsieh, Hsinchu (TW); Leif Wang, Hsinchu (TW); Ya Lan Ho, Hsinchu (TW)

Correspondence Address: TROXELL LAW OFFICE PLLC;SUITE 1404, 5205 LEESBURG PIKE, FALLS CHURCH, VA, 22041, US

(73) Assignee: Sino-American Silicon Products Inc.

(21) Appl. No.: 11/508,864

(22) Filed: Aug. 24, 2006

(30) Foreign Application Priority Data
Nov. 28, 2005 (TW) 094141739

(51) Int. Cl. C30B 7/00; C30B 17/00; C30B 21/02

(52) U.S. Cl. 117/71; 117/74

(57) ABSTRACT

A method and construction of growing wafer ingot by having a thermal shield disposed on an opening of a crucible, an opening approximating a polygonal contour disposed on the thermal shield to control gas current, heat conduction and heat radiation in ingot growth, an isotherm of condensation temperature in ingot growth approaching a polygonal form to grow the ingot into a form approximating the preset sectional form of a polygon for minimizing the material to be cut off in the subsequent process of slicing wafer ingot into chips.

### BACKGROUND OF THE INVENTION

(a) Field of the Invention

The present invention is related to a wafer ingot processing technology, and more particularly, to one that allows wafer growing into a shape that is comparatively closer to a polygonal section to minimize the amount of wastes resulted from the subsequent process in slicing the ingot into chips when the arc perimeter areas must be cut off; and to significantly increase output and reduce production cost especially in growing a square ingot for solar cell since the square ingot is at its best to minimize the raw materials to be cut off.

(b) Description of the Prior Art

As a member in the family of semiconductor, the solar cell is also known as a solar chip and silicon is so far a representative material for manufacturing solar cells generally available in the market. The power generation of the solar cell works on converting solar energy into electrical energy. There are may types of chip materials for the manufacturing of the solar PV cell and can be roughly grouped into mono-crystalline silicon, polycrystalline/Multi-crystalline silicon, and amorphous silicon, and other non-silicon materials, e.g., compound semiconductor materials including CdTe, InGaAs, and GaAs.

Furthermore, silicon is available in mono-crystalline and polycrystalline. Wherein, the constituent atoms of the mono-crystalline silicon are arranged in given rules; therefore, the product conversion efficiency is higher. In the manufacturing process of the mono-crystalline silicon, silicon metal of 99.999999999% purity is melted in a crucible 11 as illustrated in FIG. 1 of the accompanying drawings, and a mono-crystalline silicon seed in the direction marked as <100> is inserted into the liquid of the melted silicon and rotates at a rate of 2˜20 circles per minute while being pulled up at a rate of 0.3˜10 mm per minute to go through neck growth, dome growth, crystalline growth, and pedestal growth to grow into a mono-crystalline silicon ingot 20 in a diameter of 4″˜8″. This growing process is referred as a Czochralski Method.

As illustrate din FIG. 1, in the system comprised of a wafer growing furnace 10 for the manufacturing of the mono-crystalline silicon ingot, a heater 12 to heat the material inside the crucible 11 is provide in the peripheral of the crucible 11; a thermal shield 13 is provided externally to the heater 12 and the crucible 11; a thermal shield 14 is disposed over the crucible to define a thermal field for the oven 10 so to reduce thermal loss and production cost of the wafer ingot. Furthermore, a gas vent 131 is disposed below the thermal insulation 13 provided externally to both of the heater 12 and the crucible 11 to produce gas flow passing through the thermal insulation of the furnace for expelling oxides that are vulnerable to form foreign matters.

In the prior art as described above, the section of the ingot relates to circular section as illustrated in FIG. 3. When an ingot 20 is sliced into square chips that can be used in the manufacturing of the solar cell, the parts of the ingot 20 in the shadowed areas as illustrated in FIG. 3 are deemed as wastes 21 and must be cut off. The massive waste of the ingot material naturally increases the production cost of the chip.

### SUMMARY OF THE INVENTION

The primary purpose of the present invention is to provide a method and construction of growing wafer ingot for minimizing the material to be cut off in the subsequent process of slicing wafer ingot into chips by controlling gas current, heat conduction and heat radiation in ingot growth to allow an isotherm of solidification temperature of growth to approach a preferred straight side line status for the ingot to grow into a form approximating the preset sectional form of a polygon.

To achieve the purpose, a thermal shield disposed on an opening of a crucible, an opening approximating a polygonal contour disposed on the thermal shied to control gas current, heat conduction and heat radiation in ingot growth, an isotherm of solidification temperature in ingot growth approaching a polygonal form to grow the wafer into a form approximating the preset sectional form of a polygon.

Alternatively, a cover is placed at the opening of the crucible, and an opening is provided on the cover in a contour approximating that of a polygon. By controlling the weight of the cover the downward pressure of the cover, the melting liquid of silicon in the crucible is extruded towards the opening of the cover to produce an ingot in a form approximating the preset sectional form of a polygon.

### BRIEF DESCRIPTION OF THE DRAWINGS

FIG. 1 is a schematic view showing a construction of an oven for growing wafer ingot.

FIG. 2 is a schematic view showing a construction of another oven for growing wafer ingot.

FIG. 3 is a schematic view showing a section of a wafer ingot formed by a growing oven of the prior art.

FIGS. 4, 5, 6, and 7 are schematic views respectively showing a shape of a cover in the preferred embodiments of the present invention.

### DETAILED DESCRIPTION OF THE PREFERRED EMBODIMENTS

A method and construction of growing wafer ingot of the present inventions is essentially comprised of controlling gas currents, heat conduction, and heat radiation by means of a thermal shield disposed at the opening of a crucible for the isotherm of solidification temperature of the thermal filed in growing the wafer ingot to approximate a polygonal status; thus to provide a section that is comparatively closer to a polygonal section as preset to minimize the possible wastes to be cut off from the ingot when the ingot is sliced into chips in the subsequent manufacturing process.

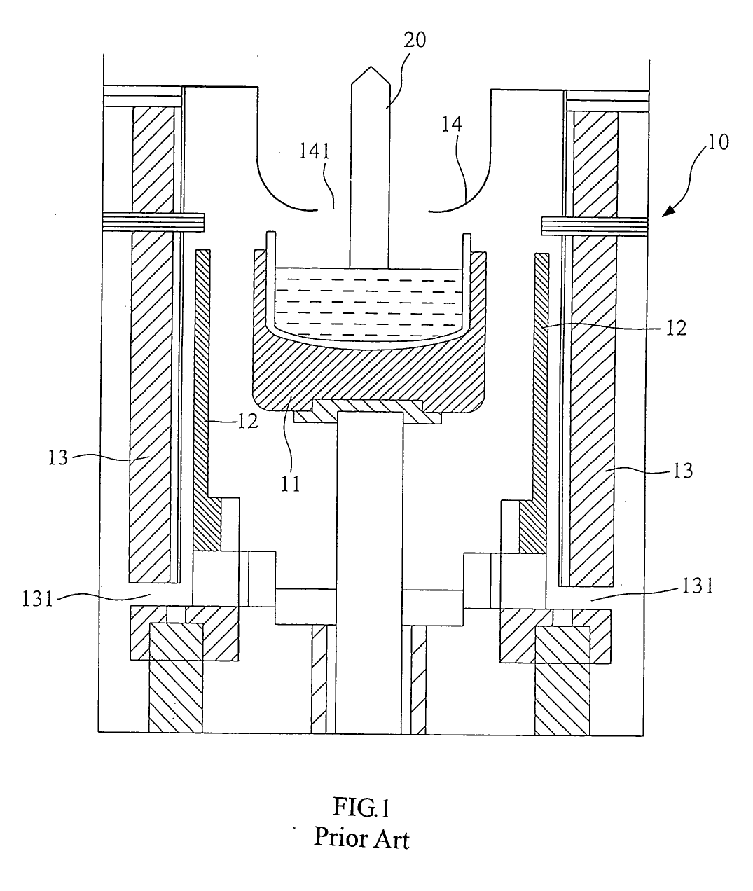

The present invention is essentially comprised of a growth furnace 10 with a crucible 11 to contain a crystal material as illustrated in FIG. 1 for the manufacturing of a wafer ingot. The crystal material relates to silicon or non-silicon material, e.g., compound semiconductor material including CdTe, InGaAs, or GaAs. A heater 12 to heat the raw material placed in the crucible 11 is disposed to the peripheral of the furnace 10 for reducing thermal loss. A thermal insulation 13 is provided externally to the heater 12 and the crucible 11. A gas vent is disposed below the thermal shield 13 to create gas currents to pass through a thermal field in the furnace for discharging oxides that are vulnerable to become foreign matters.

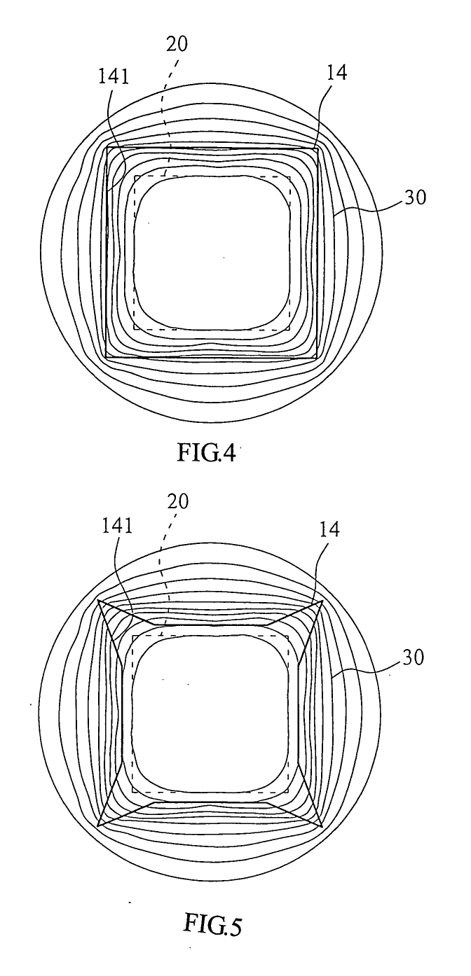

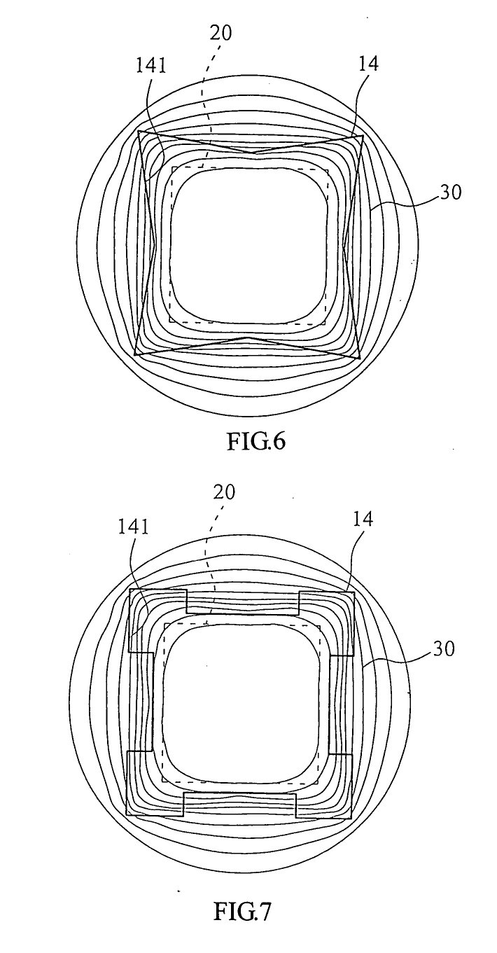

A thermal shield 14 is disposed at the opening over the curable 11 in the furnace 10 to define the thermal filed for the furnace 10 in conjunction with the thermal insulation 13. The thermal shield 14 is made of a material with excellent insulation performance and is provided with an opening 141 approximating a polygonal contour to allow the ingot 20 to pass through and to control the air currents flowing through the thermal field of the furnace 10. As illustrated in FIG. 4, the opening 141 for the thermal curtain 14 to control gas currents to be made in a square is preferred; or alternatively, in a shape as respectively illustrated in FIGS. 5, 6, and 7 with the corners of the polygonal opening 141 to be elongated or designed with a proper form for the isotherm of the solidification temperature of wafer growth to approximate a preset form, thus to allow the section of the ingot 20 to comparatively get closer to a polygonal section as present.

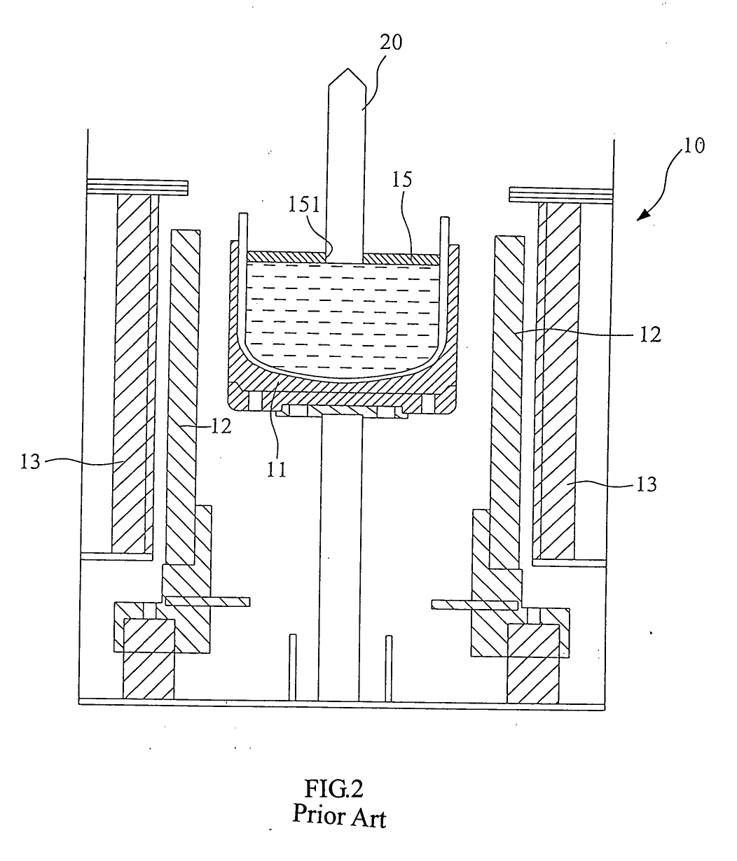

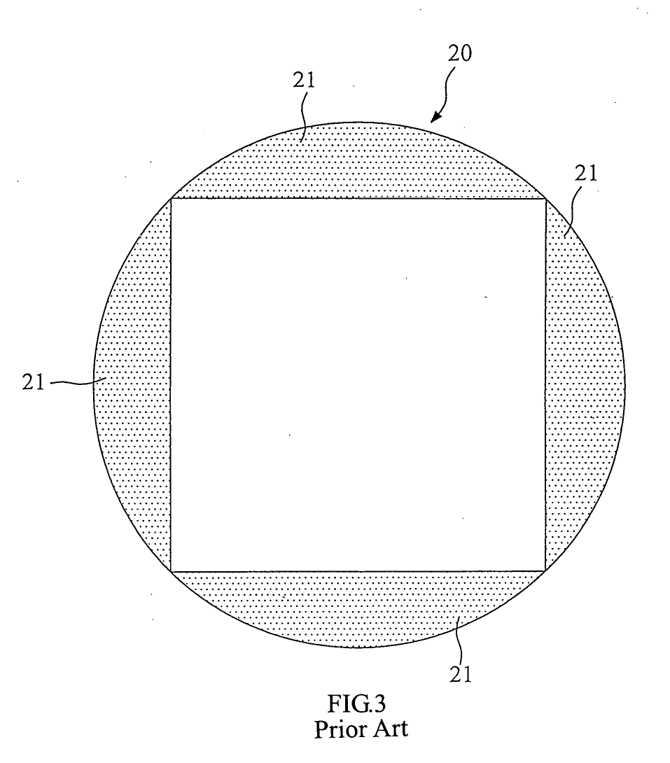

In another preferred embodiment of the present invention as illustrated in FIG. 2, it is also essentially comprised of the oven with the crucible to contain the crystal material. The heater 12 is provided to heat the raw material contained in the crucible 11. The thermal insulation 13 is disposed externally to the heater and the crucible to reduce thermal loss. A cover 15 is provided by contact at the opening of the oven 10. An opening 151 in a contour resembling that of a polygon is disposed in the cover 15. The melted silicon in the crucible is extruded towards the opening 151 by the downward pressure from the cover 15. Similarly, the ingot 20 grows with a section that is comparatively closer to a polygonal section as present.

Both preferred embodiments of the present invention are capable of producing a wafer ingot with a non-circular section to effectively minimize the amount of wastes to be cut off from the side areas of a round ingot when sliced into chips in the subsequent manufacturing process as found with the prior art.

The prevent invention provides a method of producing a wafer ingot with non-circular section, and the application for a patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. A section forming method for wafer ingot growth is comprised of having an isotherm of solidification temperature of ingot growth to approximate a polygonal status by controlling gas currents, heat conduction, and heat radiation to grow the ingot into a form approximating the preset sectional form of a polygon.

2. A section forming construction for wafer ingot growth is comprised of having a thermal shield provided at an opening of a crucible to control hot gas currents passing through a thermal insulation of growing the wafer ingot.

3. The section forming construction for wafer ingot growth as claimed in claim 2, wherein, an opening with a polygonal contour is disposed to the thermal curtain.

4. The section forming construction for wafer ingot growth as claimed in claim 3, wherein corners of the polygonal opening can be elongated.

5. The section forming construction for wafer ingot growth as claimed in claim 3, wherein corners of the polygonal opening are designed with a given shape.

6. The section forming construction for wafer ingot growth as claimed in claim 2, wherein the thermal curtain is made of a material with excellent insulation performance.

7. The section forming method or the construction for wafer ingot growth as claimed in claim 1, wherein, the raw material of the wafer ingot relates to silicon or non-silicon material.

8. The section forming method or the construction for wafer ingot growth as claimed in claim 2, wherein, the raw material of the wafer ingot relates to silicon or non-silicon material.

9. A section forming method for wafer ingot growth is comprised of a cover disposed at where the opening of the crucible is located to control passage of the wafer ingot; an opening being disposed to the cover; and the ingot being extruded into a preset shape by the downward pressure applied by the cover.

10. A section forming construction for wafer ingot growth is comprised of a cover disposed at where the opening of the crucible is located to control the passage of hot gas currents and the wafer ingot; and an opening is disposed to the over.

11. The section forming method or the construction for wafer ingot growth as claimed in claim 9, wherein, the opening in the cover indicates a polygonal contour.

12. The section forming method or the construction for wafer ingot growth as claimed in claim 10, wherein, the opening in the cover indicates a polygonal contour.

13. The section forming method or the construction for wafer ingot growth as claimed in claim 9, wherein, corners of the opening in the cover can be elongated.

14. The section forming method or the construction for wafer ingot growth as claimed in claim 10, wherein, corners of the opening in the cover can be elongated.

15. The section forming method or the construction for wafer ingot growth as claimed in claim 9, wherein, corners of the opening in the cover are designed with a given shape.

16. The section forming method or the construction for wafer ingot growth as claimed in claim 10, wherein, corners of the opening in the cover are designed with a given shape.

17. The section forming method or the construction for wafer ingot growth as claimed in claim 9, wherein, the raw material of the wafer ingot relates to silicon or non-silicon material.

18. The section forming method or the construction for wafer ingot growth as claimed in claim 10, wherein, the raw material of the wafer ingot relates to silicon or non-silicon material.
